(19) United States
(12) Patent Application Publication
(10) Pub. No.: US 2026/0130210 A1
(43) Pub. Date: May 7, 2026

(54) PACKAGE STRUCTURE AND METHOD FOR FORMING THE SAME

(71) Applicant: Taiwan Semiconductor Manufacturing Company, Ltd., Hsinchu (TW)

(72) Inventors: Shih-Wei LIU, Chiayi City (TW); Tsun-Yen WU, Hsinchu County (TW); Sing-Da JIANG, Taichung City (TW); Kathy Wei YAN, Hsinchu (TW)

(21) Appl. No.: 18/935,967

(22) Filed: Nov. 4, 2024

(51) Int. Cl. H01L 23/367; H01L 21/48; H01L 23/00; H01L 23/16; H01L 23/373; H01L 23/38; H01L 23/40; H01L 23/498; H01L 25/18; H10B 80/00

(52) U.S. Cl. CPC H10W 40/22; H10W 40/037; H10W 40/25; H10W 40/28; H10W 40/60; H10W 70/65; H10W 76/40; H10W 90/401; H10B 80/00; H10W 72/252; H10W 72/823; H10W 74/15; H10W 90/00; H10W 90/288; H10W 90/297; H10W 90/722; H10W 90/724; H10W 90/734

(57) ABSTRACT

A package structure and method for forming the same are provided. The package structure includes a cooling substrate formed on a base substrate, and the cooling substrate includes a cooling device. The package structure includes a packaged semiconductor device formed on the cooling substrate, and the packaged semiconductor device includes a first die, and the cooling device is directly below the first die.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

New packaging technologies, such as package on package (PoP), have begun to be developed, in which a top package with a device die is bonded to a bottom package, with another device die. By adopting the new packaging technologies, various packages with different or similar functions may be integrated together.

Although existing package structures and methods of fabricating package structure have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A-1O show cross-sectional representations of various stages of forming a package structure, in accordance with some embodiments of the disclosure.

FIG. 2 shows a cross-sectional representation of the cooling device, in accordance with some embodiments of the disclosure.

FIG. 3 shows a top view of the semiconductor dies and the stacked dies of FIG. 1D, in accordance with some embodiments of the disclosure.

FIG. 4 shows a top view of the semiconductor dies and the stacked dies of FIG. 1L, in accordance with some embodiments of the disclosure.

FIG. 5 shows a bottom view of the conducive connectors below the cooling substrate of FIG. 1O, in accordance with some embodiments of the disclosure.

FIGS. 6A-6C show bottom views of the trench, the openings of FIG. 1N, in accordance with some embodiments of the disclosure.

FIG. 7 shows a cross-sectional representation of a package structure, in accordance with some embodiments of the disclosure

FIG. 8 shows a cross-sectional representation of a package structure, in accordance with some embodiments of the disclosure.

FIG. 9 shows a cross-sectional representation of a package structure, in accordance with some embodiments of the disclosure.

FIG. 10 shows a cross-sectional representation of a package structure, in accordance with some embodiments of the disclosure.

FIGS. 11A-11G shows a cross-sectional representation of a package structure, in accordance with some embodiments of the disclosure.

FIG. 12 shows a cross-sectional representation of a package structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments for a package structure and method for forming the same are provided. The package structure includes a packaged semiconductor device bonded to a cooling substrate. The packaged semiconductor structure includes a die. The cooling substrate includes a cooling device (such as TEC). The hot spots are general close to the die. Thus, the cooling device of the cooling substrate is located directly below the die of the packaged semiconductor structure to help the heat transfer from the die to the outer heat spreader. In addition, the front side heat spreader and the back side heat spreader are formed on opposite sidewall surfaces of the cooling substrate to improve the heat dissipation efficiency. Therefore, the heat dissipation efficiency of the package structure is improved.

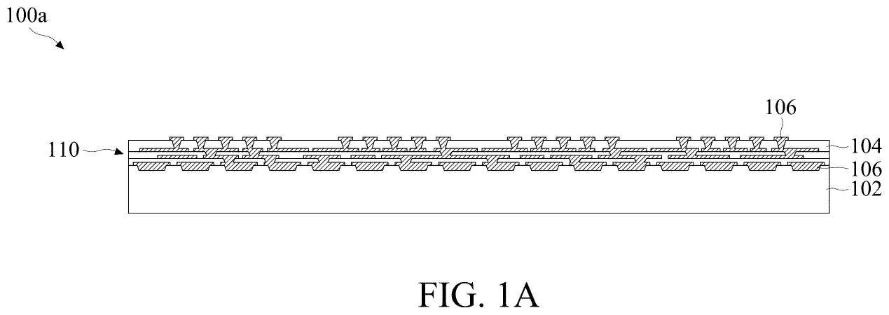

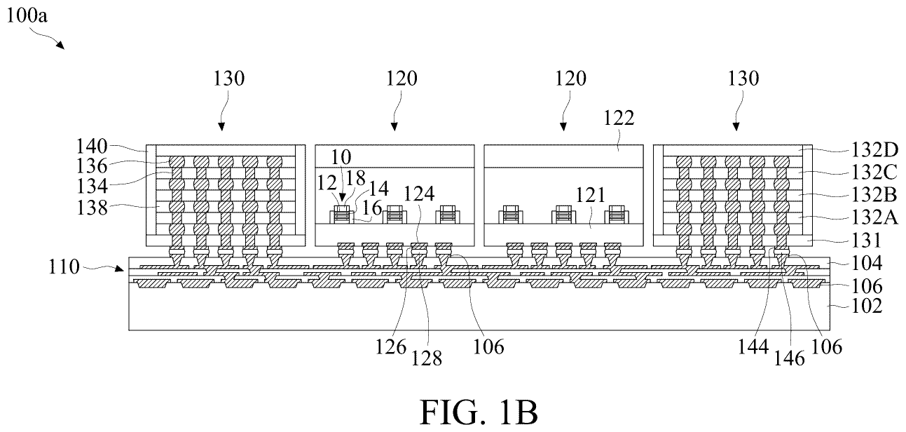

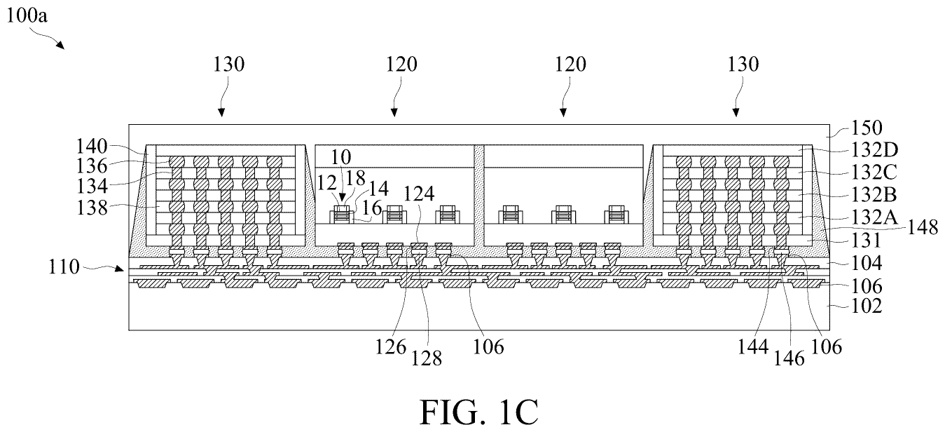

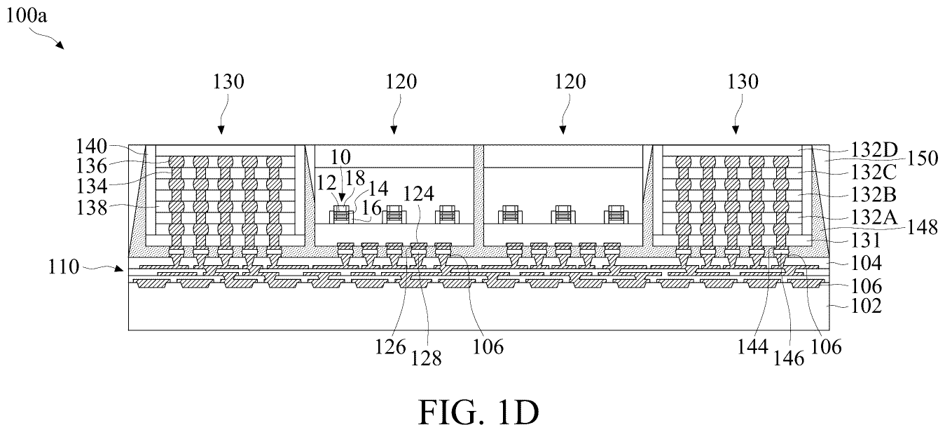

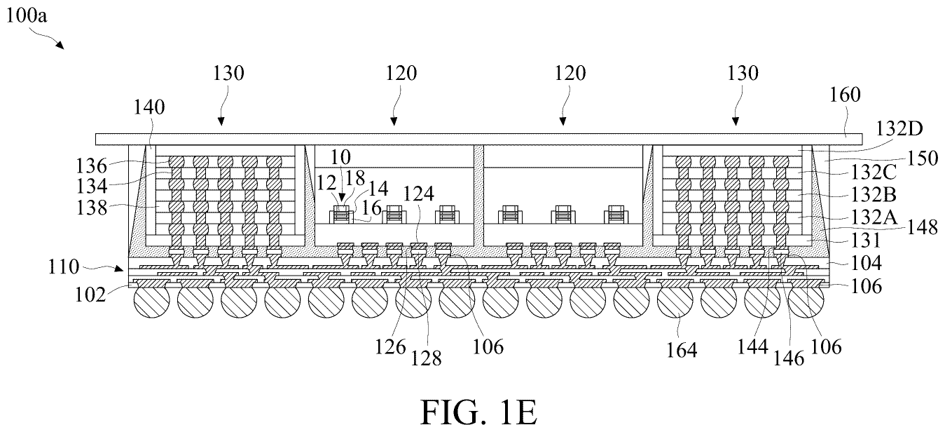

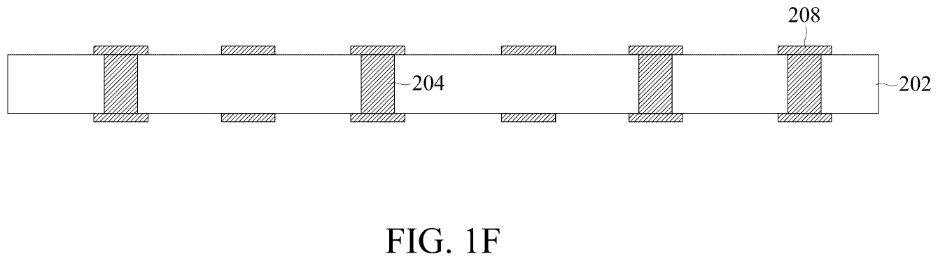

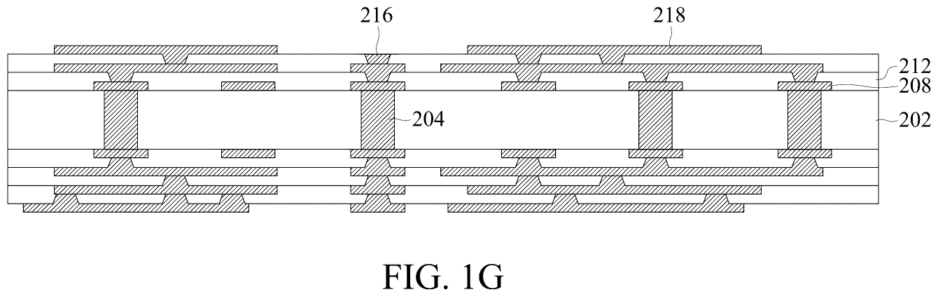

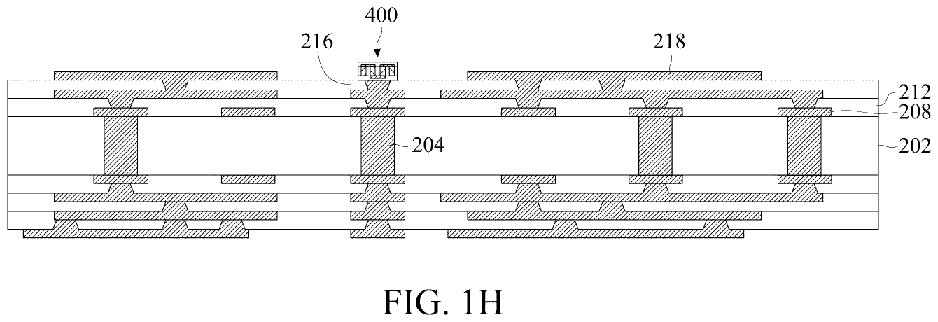

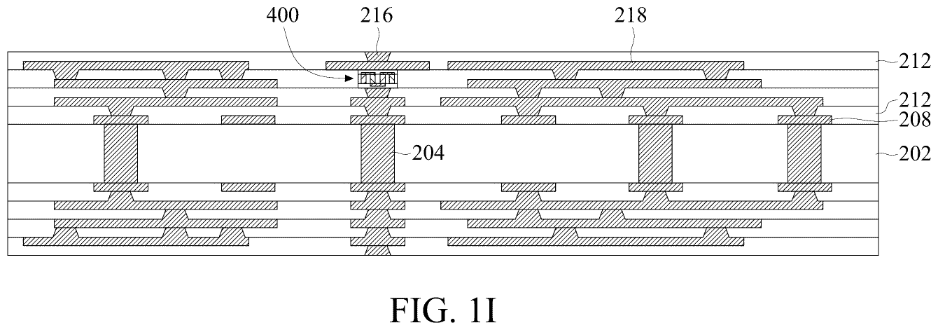

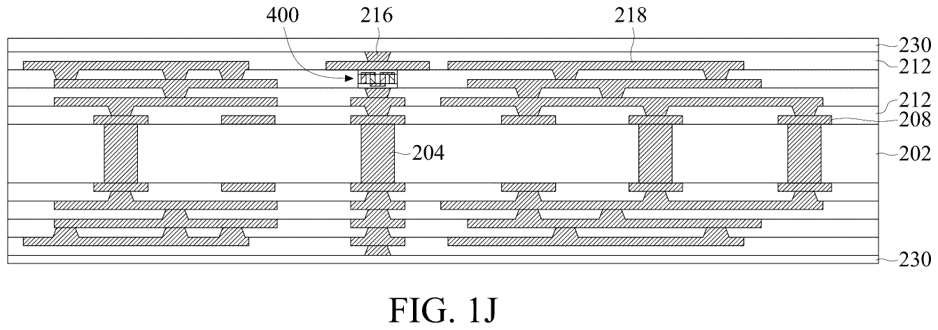

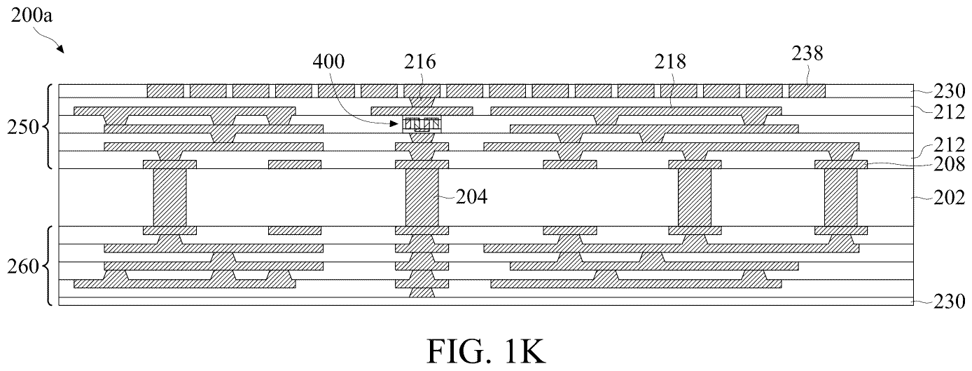

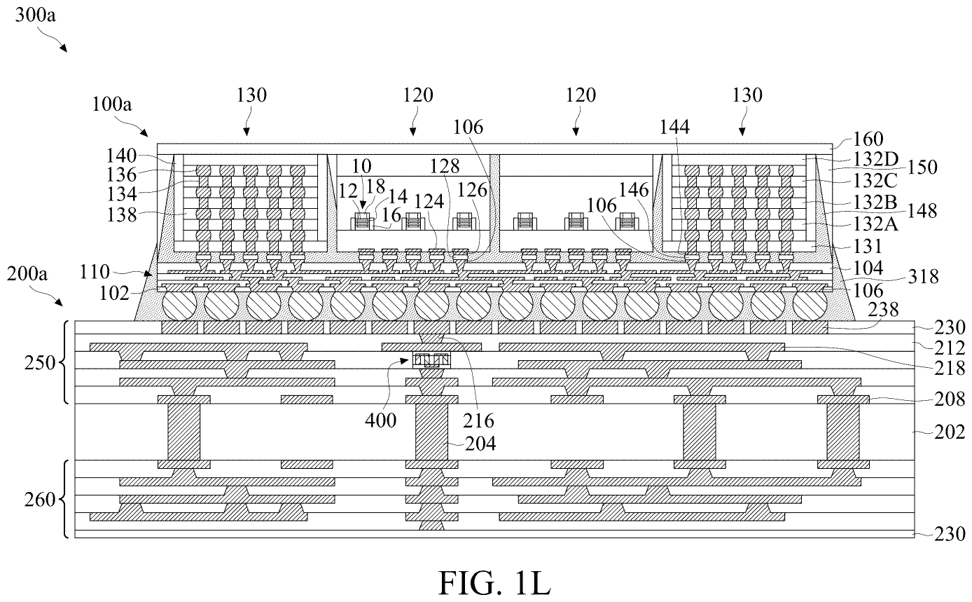

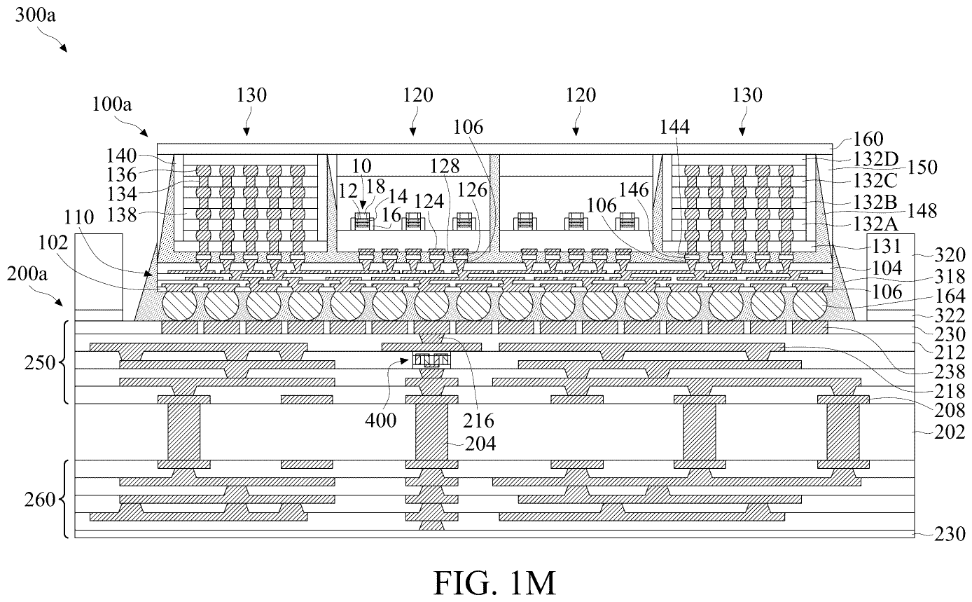

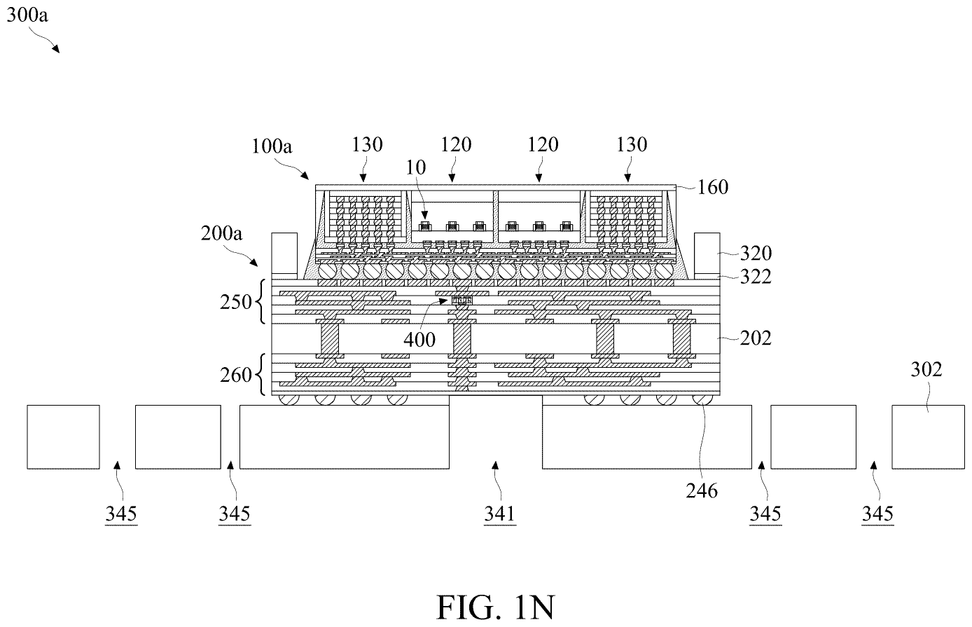

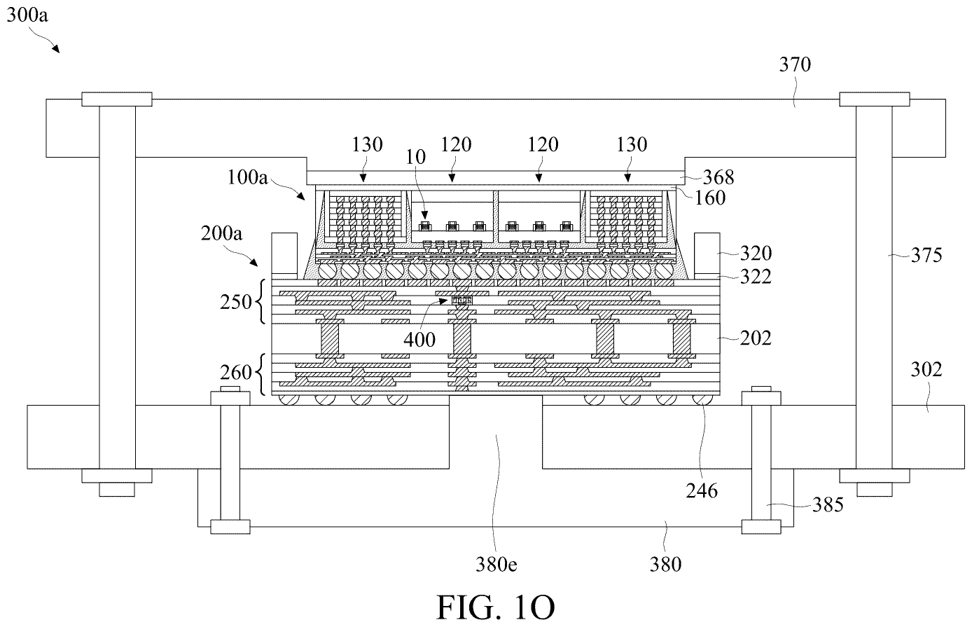

FIGS. 1A-1O show cross-sectional representations of various stages of forming a package structure 300a, in accordance with some embodiments of the disclosure.

Referring to FIG. 1A, a substrate 102 is provided. The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

An interconnect structure 110 is formed over the substrate 102. The interconnect structure 110 may be used as a redistribution (RDL) structure for routing. The interconnect structure 110 includes multiple dielectric layers 104 and multiple conductive layers 106.

The dielectric layers 104 may be made of or include one or more polymer materials. The polymer material(s) may include polybenzoxazole (PBO), polyimide (PI), one or more other suitable polymer materials, or a combination thereof. In some embodiments, the polymer material is photosensitive. In some embodiments, some or all of the dielectric layers 104 are made of or include dielectric materials other than polymer materials. The dielectric material may include silicon oxide, silicon carbide, silicon nitride, silicon oxynitride, one or more other suitable materials, or a combination thereof.

In some embodiments, some of the conductive layers 106 are exposed at or protruding from the top surface of the top of the dielectric layers 104. The exposed or protruding conductive layers 106 may serve as bonding pads where conductive bumps (such as tin-containing solder bumps) and/or conductive pillars (such as copper pillars) will be formed later.

Afterwards, as shown in FIG. 1B, a number of semiconductor dies 120 and a number of stacked dies 130 are formed over the substrate 102, in accordance with some embodiments of the disclosure.

The semiconductor die 120 is sawed from a wafer, and may be a “known-good-die”. The semiconductor die 120 may be a system-on-chip (SoC) chip. In some other embodiments, the semiconductor die 120 is a system on integrated circuit (SoIC) device that includes two or more chips with integrated function. The semiconductor die 120 is disposed over the interconnection structure 110.

The semiconductor die 120 has a substrate 121, a semiconductor structure 10 formed on the substrate 102, and a substrate 122 formed on the semiconductor structure 10. In some embodiments, the semiconductor structure 10 is a logic device. In some embodiments, the semiconductor structure 10 is a gate all around (GAA) transistor structure. In some embodiments, the logic devices are Central Processing Unit (CPU) dies, Graphic Processing Unit (GPU) dies, mobile application dies, Micro Control Unit (MCU) dies, BaseBand (BB) dies, Application processor (AP) dies, or the like.

The semiconductor structure 10 includes nanostructures (or called channel layers) 12 formed over the substrate 121, the inner spacer layers 14, the source/drain (S/D) structures 16, and the gate structure 18. The inner spacer layers 14 are adjacent to the nanostructures (or called channel layers) 12. In addition, the inner spacer layers 14 are between the gate structure 18 and the S/D structures 16. The inner spacer layers 14 are configured to separate the source/drain (S/D) structures 16 and the gate structures 18. The source/drain(S/D) structure or region(s) may refer to a source or a drain, individually or collectively dependent upon the context.

In some embodiments, the nanostructures 12 are made of semiconductor materials, such as Si or SiGe. In some embodiments, the inner spacer layers 14 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the S/D structures 16 are made of any applicable material, such as Ge, Si, GaAs, AlGaAs, SiGe, GaAsP, SiP, SiC, SiCP, or a combination thereof.

The gate structure 18 includes a gate dielectric layer and a gate electrode layer. The nanostructures 12 are surrounded by (e.g. wrapped in) the gate dielectric layer. In some embodiments, the gate dielectric layer includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, another suitable high-k dielectric material, or a combination thereof. In some embodiments, the gate electrode layer includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof.

The substrate 121 and the substrate 122 may be a semiconductor wafer such as a silicon wafer. Alternatively or additionally, the substrate 121 and the substrate 122 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP. In some embodiments, the substrate 121 and the substrate 122 are made of silicon (Si) substrate.

In some embodiments, a number of conductive pads 124 are formed below the semiconductor die 120, and each of the conductive pads 124 is bonded to the conductive layer 126. Each of the conductive layers 126 is bonded to each of the conductive layers 106 through a number of conductive connectors 128.

The conductive pads 124 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad 124 is formed by an electroplating, electroless plating, printing, chemical vapor deposition (CVD) process or physical vapor deposition (PVD) process.

The conductive layers 126 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 126 are formed by an electroplating, electroless plating, printing, a chemical vapor deposition (CVD) process, or a physical vapor deposition (PVD) process.

The conductive connector 128 is made of solder materials, such as tin (Sn), tin-silver (SnAg), tin-lead (SnPb), tin-copper (SnCu), tin-silver-copper (SnAgCu), tin-silver-zinc (SnAgZn), tin-zinc (SnZn), tin-bismuth-indium (SnBiIn), tin-indium (SnIn), tin-gold (SnAu), tin-zinc-indium (SnZnIn), tin-silver-Antimony (SnAgSb) or another applicable material. In some embodiments, the conductive connectors 128 are formed by electroplating, electroless plating, printing, a chemical vapor deposition (CVD) process, or a physical vapor deposition (PVD) process.

The stacked die 130 is disposed over the interconnect structure 110. The stacked die 130 is formed adjacent to the semiconductor die 120. The stacked die 130 includes a number of semiconductor dies 132A, 132B, 132C, 132D. In some embodiments, the semiconductor dies 132A, 132B, 132C, 132D are memory dies. The semiconductor die 120 has a different function from each of the plurality of the memory dies. The memory dies may include static random access memory (SRAM) devices, dynamic random access memory (DRAM) devices, high bandwidth memory (HBM) or another memory dies. The number of the semiconductor dies 132A, 132B, 132C, 132D are not limited to four, and the number can be adjusted according to the actual application.

The semiconductor dies 132A, 132B, 132C, 132D are stacked on a buffer die (or base die) 131 that performs as a logic circuit. The semiconductor dies 132A, 132B, 132C, 132D are bonded to each other by a number of bonding structures 136. A number of through substrate vias (TSVs) 134 are formed in the semiconductor dies 132A, 132B, 132C, 132D. The signal between the semiconductor dies 132A, 132B, 132C, 132D may be transferred through the through substrate vias (TSVs) 134 and the bonding structures 136.

Afterwards, an underfill layer 138 is formed between the semiconductor dies 132A, 132B, 132C, 132D to protect the bonding structures 136. In some embodiments, the underfill layer 138 includes an epoxy-based resin with fillers dispersed therein. The fillers may include insulating fibers, insulating particles, other suitable elements, or a combination thereof. A molding compound 140 protects the semiconductor dies 132A, 132B, 132C, 132D. In some embodiments, the molding compound 140 may include an epoxy-based resin with fillers dispersed therein. The fillers may include insulating fibers, insulating particles, other suitable elements, or a combination thereof. In some embodiments, the size and/or density of the fillers dispersed in the underfill layer 138 is smaller than those dispersed in the molding compound 140.

In some embodiments, a number of conductive pads 144 are formed on the stacked die 130, and each of the conductive pads 144 is bonded to the conductive layer 106 of the interconnect structure 110 through a conductive connector 146.

The conductive pads 144 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive pad 144 is formed by an electroplating, electroless plating, printing, chemical vapor deposition (CVD) process or physical vapor deposition (PVD) process.

The conductive connector 146 is made of solder materials, such as tin (Sn), SnAg, SnPb, SnAgCu, SnAgZn, SnZn, SnBiIn, SnIn, SnAu, SnPb, SnCu, SnZnIn, SnAgSb or another applicable material. In some embodiments, the conductive connector 146 is formed by electroplating, electroless plating, printing, chemical vapor deposition (CVD) process or physical vapor deposition (PVD) process.

Afterwards, as shown in FIG. 1C, an underfill layer 148 is formed between the semiconductor die 120, the stacked die 130 and the interconnect structure 110, in accordance with some embodiments of the disclosure. The underfill layer 148 surrounds and protects the conductive layers 126, the conductive connectors 128, the conductive pad 144 and the conductive connectors 146. In some embodiments, the underfill layer 148 is in direct contact with the conductive layers 126, the conductive connectors 128, the conductive pad 144 and the conductive connectors 146.

In some embodiments, the underfill layer 148 is made of or includes a polymer material. The underfill layer 148 may include an epoxy-based resin. In some embodiments, the underfill layer 148 includes fillers dispersed in the epoxy-based resin.

In some embodiments, the formation of the underfill layer 148 involves an injecting process, a spin-on process, a dispensing process, a film lamination process, an application process, or a combination thereof. In some embodiments, a thermal curing process is used during the formation of the underfill layer 148.

Afterwards, a first package layer 150 is formed over the underfill layer 148. The first package layer 150 is also formed over the substrate 122. There is an interface between the underfill layer 148 and the package layer 150, and the interface is lower than the top surface of the semiconductor die 120.

The first package layer 150 surrounds and protects the semiconductor dies 120 and the stacked dies 130. In some embodiments, the first package layer 150 is in direct contact with the semiconductor die 120 and the stacked die 130.

The first package layer 150 is made of a molding compound material. The molding compound material may include a polymer material, such as an epoxy-based resin with fillers dispersed therein. In some embodiments, a liquid molding compound material is applied over the semiconductor dies 120 and the stacked dies 130. The liquid molding compound material may flow into a space between the semiconductor dies 120 and the stacked dies 130. A thermal process is then used to cure the liquid molding compound material and to transform it into the first package layer 150. In some embodiments, the first package layer 150 is formed by compression molding process or transfer molding process, or another applicable process.

Afterwards, as shown in FIG. 1D, a portion of the first package layer 150 is removed to expose the top surface of the substrates 122 of the semiconductor dies 120, in accordance with some embodiments of the disclosure. In some embodiments, the portion of the first package layer 150 is removed by a planarization process, such as a chemical mechanical polishing (CMP) process.

Next, as shown in FIG. 1E, a carrier substrate 160 is formed over the package layer 150, and the substrate 102 is thinned from the back surface until the conductive layers 106 are exposed, in accordance with some embodiments of the disclosure. In other words, a portion of the interconnect structure 110 is removed. As a result, the conductive layers 106 of the interconnect structure 110 are exposed.

The carrier substrate 160 is configured to provide temporary mechanical and structural support during subsequent processing steps, in accordance with some embodiments. The carrier substrate 160 includes glass, silicon oxide, aluminum oxide, metal, the like, or a combination thereof, in accordance with some embodiments. The carrier substrate 160 includes a metal frame, in accordance with some embodiments.

Afterwards, a number of the conductive connectors 164 are formed over the exposed conductive layers 106 of the interconnect structure 110. The conductive connectors 164 are electrically connected to the conductive layers 106 of the interconnect structure 110. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Afterwards, as shown in FIG. 1F, a core substrate 202 is provided, in accordance with some embodiments of the disclosure. The core substrate 202 includes an insulation layer with conductive layers on both sides of the insulation layer, in accordance with some embodiments. The core substrate 202 may be a core substrate. In some embodiments, the core substrate 202 is a double-sided copper clad laminate (CCL). The insulation layer may be an organic substrate, a ceramic substrate, a pre-impregnated composite fiber (prepreg), Ajinomoto Build-up Film (ABF), paper, glass fiber, non-woven glass fabric, or another applicable materials. The conductive layers may be one or more layers of copper, nickel, aluminum, other conductive materials, or a combination thereof laminated or formed onto opposing sides of the insulation layer.

Next, a conductive plug 204 is formed through the core substrate 202. The conductive plug 204 is formed by forming an opening (not shown) in the core substrate 202, and the opening is through the top surface and the bottom surface of the core substrate 202. In some embodiments, the opening is formed by laser drilling, mechanical drilling, etching, or the like. The openings may have a rectangular, circular, or other shape in a top-down view. Next, the conductive material is filled into the opening to form the conductive plug 204.

In addition, the conductive layers 208 are formed on the conductive plug 204 and on the core substrate 202. The conductive layers 208 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive layers 208 are formed by an electroplating, electroless plating, printing, a chemical vapor deposition (CVD) process, or a physical vapor deposition (PVD) process.

Prior to depositing a conductive material within the openings (not shown), a surface preparation process may be performed. The surface preparation process may include cleaning the exposed surfaces of the core substrate 202 with one or more cleaning solutions (e.g., sulfuric acid, chromic acid, neutralizing alkaline solution, water rinse etc.) to remove or reduce soil, oils, and/or native oxide films. A desmear process may be performed to clean the area near the openings (not shown), which may have been smeared with the material of the insulation layer of the core substrate 202 that was removed to form the openings.

Next, as shown in FIG. 1G, dielectric layers 212 are formed on front side and back side of the core substrate 202, and conductive vias 216 and conductive layers 218 are formed in the dielectric layers 212, in accordance with some embodiments of the disclosure.

The dielectric layers 212 may be made of or include one or more polymer materials. The polymer material(s) may include polybenzoxazole (PBO), polyimide (PI), benzocyclobutene (BCB), another applicable polymer materials, or a combination thereof. In some embodiments, the polymer material is photosensitive. In some embodiments, some or all of the dielectric layers 212 are made of or include dielectric materials other than polymer materials. The dielectric material may include silicon oxide, silicon carbide, silicon nitride, silicon oxynitride, one or more other suitable materials, or a combination thereof.

The conductive vias 216 and the conductive layers 218 are made of metal materials, such as copper (Cu), copper alloy, aluminum (Al), aluminum alloy, tungsten (W), tungsten alloy, titanium (Ti), titanium alloy, tantalum (Ta) or tantalum alloy. In some embodiments, the conductive vias 216 and conductive layers 218 are formed by an electroplating, electroless plating, printing, a chemical vapor deposition (CVD) process, or a physical vapor deposition (PVD) process.

Afterwards, as shown in FIG. 1H, a cooling device 400 is formed on the conductive layers 218, in accordance with some embodiments of the disclosure. More specifically, the cooling device 400 is directly formed on the conductive plug 204 and the conductive vias 216. The cooling device 400 is electrically and thermally connected to the conductive plug 204 and the conductive vias 216. The cooling device 400 is in direct contact with the conductive vias 216. The cooling device 400 is configured to transfer heat generated by the semiconductor die 120 or stacked die 130 to the external environment.

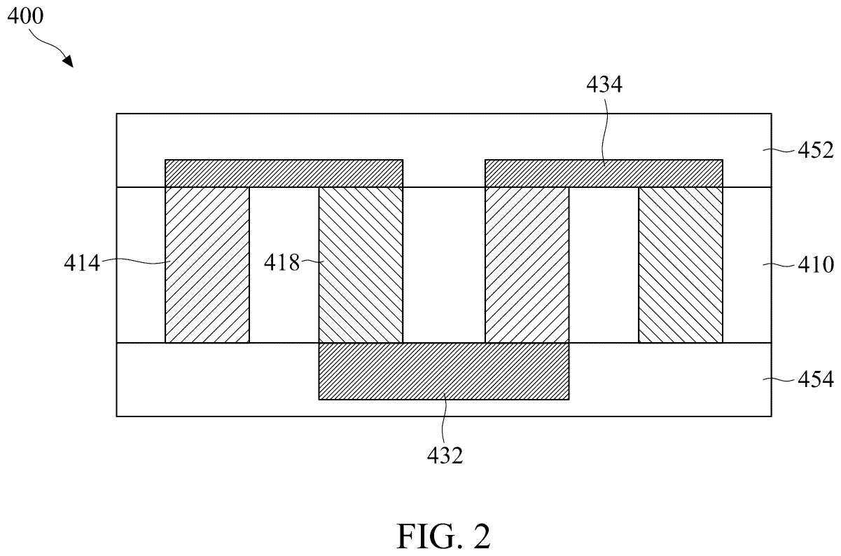

FIG. 2 shows a cross-sectional representation of the cooling device 400, in accordance with some embodiments of the disclosure.

In some embodiments, the cooling device is a thermal electronic cooler (TEC). The cooling device 400 includes a number of first regions 414 and a number of second regions 418 are between a first plate 452 and a second plate 454. The first regions 414 and the second regions 418 are formed in a substrate 410 by performing a doping process, such as ion implantation process. The first regions 414 and the second regions 418 are connected to each other by conductive layers 432 and conductive layers 434. The first plate 452 and the second plate 454 are heat conductors and electrical insulators.

In some embodiments, the first regions 414 are made of n-type semiconductor material. In some embodiments, the second regions 418 are made of p-type semiconductor material. In some embodiments, the first plate 452 and the second plate 454 are made of ceramic (for example, Be₂TE₃, which is an effective heat conductor and an electrical insulator. The alternating p and n-type semiconductor pillars are placed thermally in parallel to each other and electrically in series and then joined with a thermally conducting plate on each side. When a voltage is applied to the free ends of the two semiconductors there is a flow of DC current across the junction of the semiconductors, causing a temperature difference. The side with the cooling plate absorbs heat which is then transported by the semiconductor to the other side of the device.

In some embodiments, when a DC electric current flows through the cooling device 400, it brings heat from one side to the other, so that one side gets cooler while the other gets hotter. In some embodiments, the first plate 452 absorbs heat which is then transported by the first regions 414 and the second regions 418 is transmitted to the second plate 454.

Next, as shown in FIG. 1I, the dielectric layers 212 are formed on front side and back side of the core substrate 202, and the conductive vias 216 and the conductive layers 218 are formed in the dielectric layers 112, in accordance with some embodiments of the disclosure. The dielectric layers 212 are formed on and cover the cooling device 400.

Afterwards, as shown in FIG. 1J, a protective layer 230 is formed on and below the dielectric layers 212, the conductive vias 216 and the conductive layers 218, in accordance with some embodiments of the disclosure. The protective layer 230 may be a solder resist or the like formed over the conductive vias 216 and the conductive layers 218 to protect the underlying layers from external damage.

Next, as shown in FIG. 1K, the protective layer 230 is patterned to form trenches (not shown), and conductive materials are formed in the trenches to form the conductive pads 238, in accordance with some embodiments of the disclosure. As a result, a front side interconnect structure 250 is formed on the core substrate 202, and a back side interconnect structure 260 is formed below the core substrate 202. A cooling substrate 200a is formed with the cooling device 400 embedded in the front side interconnect structure 250.

It should be noted that the cooling device 400 is formed in the front side interconnect structure 250 of the cooling substrate 200a. The cooling device 400 is electrically connected to the conducive vias 216 and the conductive plug 204 of the front side interconnect structure 250.

It should be noted that no logic device (transistor) is formed in the cooling substrate 200a, and the cooling substrate 200a provides the electrical and thermal routings.

Afterwards, as shown in FIG. 1L, the packaged semiconductor structure 100a is formed on the cooling substrate 200a to form a package structure 300a, in accordance with some embodiments of the disclosure. The packaged semiconductor structure 100a is bonded to the cooling substrate 200a by connecting the conductive connectors 164 to the conductive pads 238. The conductive connectors 164 of the packaged semiconductor structure 100a is electrically connected to the conductive pads 238 of the cooling substrate 200a.

Next, an underfill layer 318 is formed to surround and protect the conductive connectors 164 and the conductive pads 238. In some embodiments, the underfill layer 318 is in direct contact with the conductive connectors 164 and the conductive pads 238. In some embodiments, the underfill layer 318 is made of or includes a polymer material. The underfill layer 318 may include an epoxy-based resin. In some embodiments, the underfill layer 318 includes fillers dispersed in the epoxy-based resin.

In some embodiments, the formation of the underfill layer 318 involves an injecting process, a spin-on process, a dispensing process, a film lamination process, an application process, or a combination thereof. In some embodiments, a thermal curing process is used during the formation of the underfill layer 318.

Next, as shown in FIG. 1M, a stiffener 320 is formed on edge portions of the protective layer 230, in accordance with some embodiments of the disclosure. The packaged semiconductor structure 100a is surrounded by the stiffener 320.

The stiffener 320 is used to protect the packaged semiconductor structure 100a. The stiffener structure 320 is formed on the protective layer 230 by the adhesive 322. In some embodiments, the sidewall surface of the stiffener structure 320 is substantially aligned with the sidewall surface of the core substrate 202 of the cooling substrate 200a.

The stiffener structure 320 can reduce this warpage of the packaged semiconductor structure 100a. In some embodiments, the stiffener 320 includes copper (Cu), copper alloy, copper tungsten (CuW), or another applicable material. In some embodiments, the adhesive 322 is made of polymer having a good thermal conductivity. In some embodiments, the stiffener 320 has a ring shaped structure when seen from a top-view.

Afterwards, as shown in FIG. 1N, a base substrate 302 is formed below the cooling substrate 200a, in accordance with some embodiments of the disclosure. The conductive connectors 246 are formed below the back side interconnect structure 260 to electrically connect the base substrate 302. The package structure 300a with the cooling substrate 200a and the packaged semiconductor structure 100a is bonded to the base substrate 302 by the conductive connectors 246. It should be noted that no logic device (transistor) is formed in the base substrate 302, and the base substrate 302 provides the electrical and thermal routings.

A trench 341 is pre-formed in the base substrate 302, and opening 345 are pre-formed in the base substrate 302 before the base substrate 302 bonded to the cooling substrate 200a. The trench 341 is configured to dispose the back side spreader 380 (formed later), and the openings 345 are configured to dispose the fastening element 375 (formed later) and the fastening element 385 (formed later).

The base substrate 302 is configured to provide temporary mechanical and structural support during subsequent processing steps, in accordance with some embodiments. The base substrate 302 includes glass, silicon oxide, aluminum oxide, metal, the like, or a combination thereof, in accordance with some embodiments. The base substrate 302 includes a metal frame, in accordance with some embodiments. In some embodiments, the trenches 341 and the opening 345 are formed by laser drilling, mechanical drilling, etching, or the like. The trenches 341 and the opening 345 may have a rectangular, circular, or other shape in a top-down view.

Next, as shown in FIG. 1O, a front side heat spreader 370 is formed on the packaged semiconductor structure 100a, and a back side spreader 380 is formed below the core substrate 202 of the cooling substrate 200a, in accordance with some embodiments of the disclosure. There is a thermal interface material (TIM) 368 between the packaged semiconductor structure 100a and the front side heat spreader 370. The TIM 368 is configured to dissipate thermal energy or heat from the semiconductor die 120 or the stacked dies 130 to the front side heat spreader 370.

In some embodiments, the TIM 368 includes aluminum oxide, boron nitride, aluminum nitride, aluminum, copper, silver, indium, a combination thereof, or another applicable material. In some embodiments, the TIM 368 includes a polymer material. In some embodiments, the TIM 368 includes other materials, such as a metallic-based or solder-based material comprising silver, indium paste, or another applicable material. In some other embodiments, the TIM 368 includes a film-based or sheet-based material, such as a sheet-based material including synthesized carbon nanotubes (CNTs) or a thermally conductive sheet having vertically oriented graphite fillers.

The front side heat spreader 370 is formed on the TIM 368. The front side heat spreader 370 is physically and thermally connected to the TIM 368. The front side heat spreader 370 is configured to dissipate the heat from the semiconductor dies 120 or the stacked dies 130 to the external environment by the TIM 368.

In some embodiments, the front side heat spreader 370 includes fins for radiative heat dissipation to the surrounding environment. In some embodiments, the front side heat spreader 370 includes at least one thermal conductive plate. In some other embodiments, the front side heat spreader 370 includes another suitable heat transferring structure to help reduce heat generated by the semiconductor dies 120 or the stacked dies 130.

In some embodiments, the area of the front side heat spreader 370 is greater than the sum of the areas of the semiconductor dies 120 and the stacked dies 130. The front side heat spreader 370 is added after the packaged semiconductor structure 100a is formed on the cooling substrate 200a.

The back side spreader 380 is formed below the cooling substrate 200a. The area of the back side spreader 380 is greater than the area of the cooling substrate 200a. In some embodiments, the back side spreader 380 includes fins for radiative heat dissipation to the surrounding environment. In some embodiments, the back side spreader 380 includes at least one thermal conductive plate.

The backside heat spreader 380 has an extending portion 380e through the base substrate 302. The extending portion 380e of the backside heat spreader 380 is connected to the cooling substrate 200a to transfer heat more efficiency. The extending portion 380e of the backside heat spreader 380 is formed through the trench 341.

In some embodiments, the extending portion 380e of the backside heat spreader 380 is directly below the semiconductor dies 120 since the hot spots are mainly at the region of the semiconductor dies 120. In some embodiments, the extending portion 380e of the backside heat spreader 380 is directly below the cooling device 400 of the cooling substrate 200a. The heat generated from the semiconductor dies 120 or the stacked die 130 can be transferred to the backside heat spreader 380 by the cooling device 400 and the conductive plug 204 and the conductive layer 208.

A fastening element 375 is formed between the front side heat spreader 370 and the base substrate 302. The fastening element 375 may physically fasten the front side heat spreader 370 and the base substrate 302 together. The fastening elements 375 include clamps, knob clamps, clips, other elements.

A fastening element 385 is formed between the base substrate 302 and the backside heat spreader 380. The fastening element 385 may physically fasten the base substrate 302 and backside heat spreader 380 together. The fastening elements 385 include clamps, knob clamps, clips, other elements.

It should be noted that the hot spots are usually formed close to the semiconductor dies 120. Therefore, the cooling device 400 is formed in the cooling substrate 200a and is directly below the semiconductor dies 120 to transfer heat generated from the semiconductor dies 120 more efficiency. In addition, the conductive vias 216 are electrically connected to the cooling device 400 of the cooling substrate 200a to transfer the heat. The backside heat spreader 380 and the front side heat spreader 370 work together to improve the thermal performance. The cooling substrate 200a with embedded cooling device 400 can transfer the heat more efficiency.

Furthermore, the heat can be transferred from front side and back side of the package structure 300a. The heat transfer path is not only front side, but also back side. The heat dissipation efficiency can be further improved by the double side transfer path.

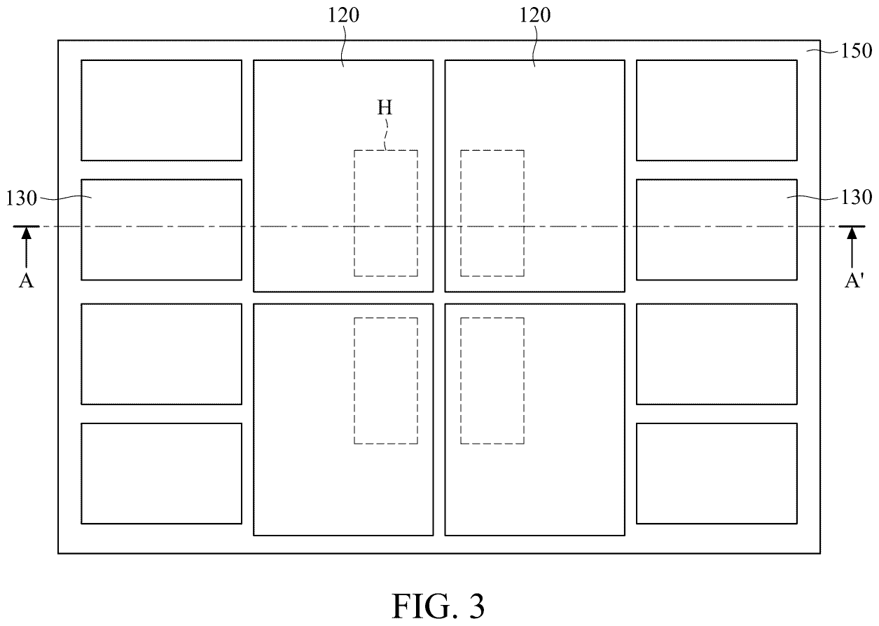

FIG. 3 shows a top view of the semiconductor dies 120 and the stacked dies 130 of FIG. 1D, in accordance with some embodiments of the disclosure. FIG. 1D shows the cross-sectional representation of the package structure 100a along the AA′ line of FIG. 3. Some elements are not shown for clarity.

As shown in FIG. 3, the stacked dies 130 are formed adjacent to the semiconductor dies 120. The four semiconductor dies 120 are surrounded by the eight the stacked dies 130. The number of the semiconductor dies 120 and the stacked dies 130 can be adjusted according to the actual application. The mainly hot spots are located at the hot spot region H of the semiconductor dies 120 since the semiconductor dies 120 are high power consumption die relative to the stacked die 130.

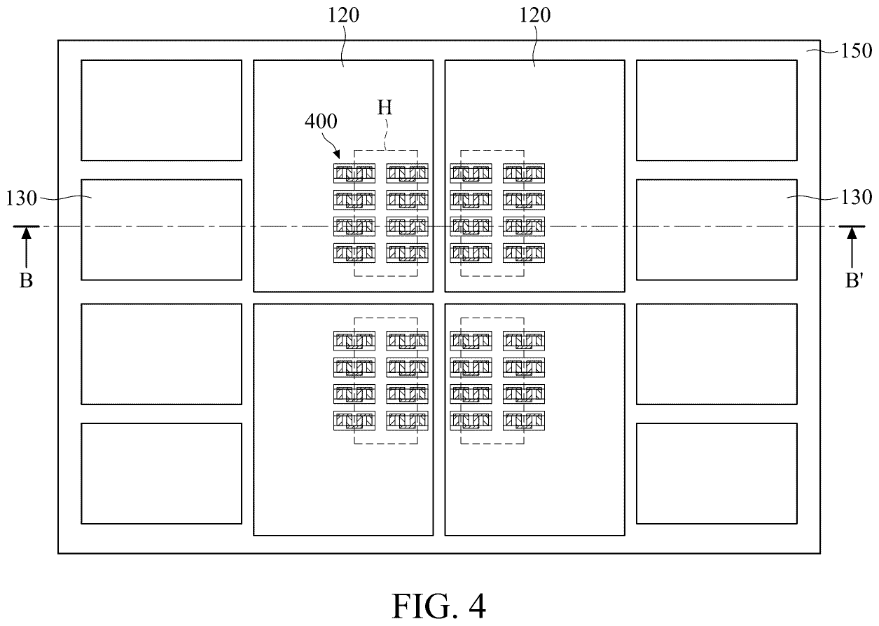

FIG. 4 shows a top view of the semiconductor dies 120 and the stacked dies 130 of FIG. 1L, in accordance with some embodiments of the disclosure. FIG. 1L shows the cross-sectional representation of the package structure 100a along the BB′ line of FIG. 4. Some elements are not shown for clarity.

As shown in FIG. 4, the positional relationship between the cooling device 400 and the semiconductor dies 120 are shown. After the semiconductor device structure 100a is bonded to the cooling substrate 200a, a number of cooling devices 400 are formed below the hot spot region H of the semiconductor dies 120 to transfer the heat more efficiently. There are eight cooling devices 400 in the front side interconnect structure 250 of each of the cooling substrate 200a. The number and the layout of cooling devices 400 can be adjusted according to the actual application.

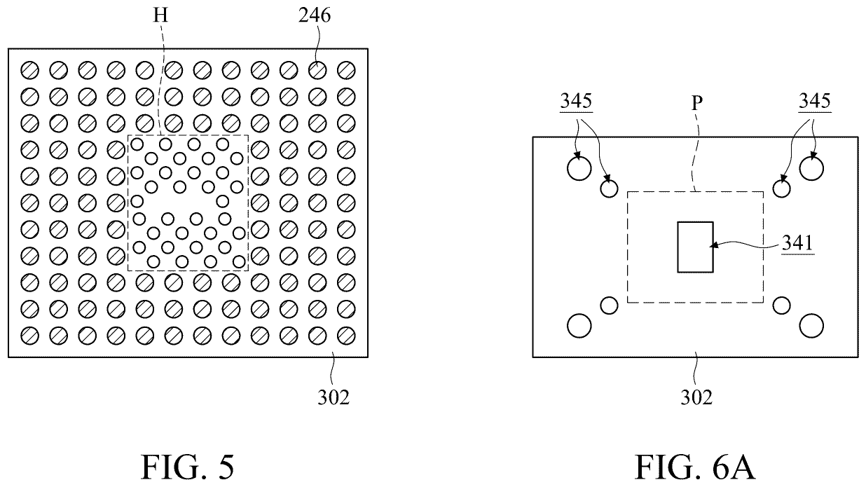

FIG. 5 shows a bottom view of the conducive connectors 246 below the cooling substrate 200a of FIG. 1O, in accordance with some embodiments of the disclosure.

As shown in FIG. 5, some of the conducive connectors 246 are directly below the hot spot region H of the semiconductor dies 120. The heat can be transferred from the semiconductor dies 120, through the cooling device 400 and the conducive vias 216 and the conductive plug 204 of the front side interconnect structure 250 to the back side spreader 380.

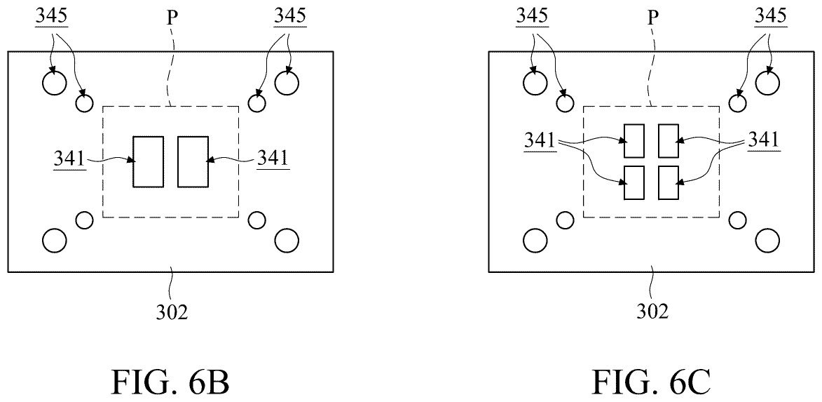

FIGS. 6A-6C show bottom views of the trench 341 and the openings 345 of FIG. 1N, in accordance with some embodiments of the disclosure.

As shown in FIG. 6A, the trench 341 is configured to dispose the back side spreader 380, and the openings 345 are configured to dispose fastening element 375 and the fastening element 385. One trench 341 is surrounded by eight openings 345. The trench 341 is at the package area P, and the openings 345 are located outside of the package area P. The trench 341 has a rectangular shape when seen from a top-view. The openings 345 are at the diagonal line with respect to the trench 341.

As shown in FIG. 6B, two trenches 341 are surrounded by four openings 345.

As shown in FIG. 6C, four trenches 341 are surrounded by four openings 345. The number and the layout of the trench 341 and the number of the openings 345 can be adjusted according to actual application.

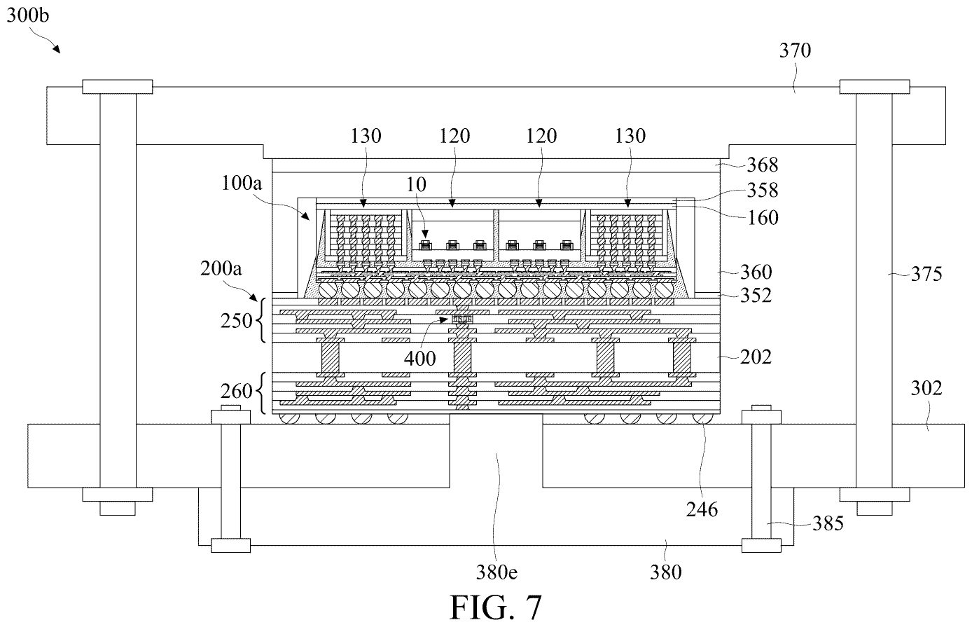

FIG. 7 shows a cross-sectional representation of a package structure 300b, in accordance with some embodiments of the disclosure. The package structure 300b is similar to, or the same as, the package structure 300a shown in FIGS. 1A-1O. Processes and materials used to form semiconductor device structure 300b may be similar to, or the same as, those used to form the semiconductor device structure 300a and a detailed description thereof is not repeated herein.

The difference between FIG. 7 and FIG. 1O is that there is an additional lid structure 360 between the front side heat spreader 370 and the package structure 300a. A TIM 358 is formed on the semiconductor device structure 100a, and between the lid structure 360 and the semiconductor device structure 100a. The TIM 368 is formed on the lid structure 360 and between the lid structure 360 and the front side heat spreader 370. The TIM 368 and the TIM 358 are formed on opposite sidewall surfaces of the lid structure 360. In some embodiments, the width of the TIM 368 is greater than the width of the TIM 358.

In some embodiments, the TIM 358 includes aluminum oxide, boron nitride, aluminum nitride, aluminum, copper, silver, indium, a combination thereof, or another applicable material. In some embodiments, the TIM 358 includes a polymer material. In some embodiments, the TIM 358 includes other materials, such as a metallic-based or solder-based material comprising silver, indium paste, or another applicable material. In some other embodiments, the TIM 358 includes a film-based or sheet-based material, such as a sheet-based material including synthesized carbon nanotubes (CNTs) or a thermally conductive sheet having vertically oriented graphite fillers.

The heat generated from the semiconductor die 120 and the stacked die 130 dissipate to the lid structure 360, and then dissipate to front side heat spreader 370. The lid structure 360 is attached to the protective layer 230 of the cooling substrate 200a by an adhesive 352. The lid structure 360 has a main portion 360a and leg portions 360b. The leg portions 360b extends from the main portion 360a to connect the adhesive 352.

In some embodiments, the lid structure 360 has a high thermal conductivity, for example, between about 200 W/mK to about 400 W/mK. In some embodiments, the lid structure 360 is made of copper (Cu), copper alloy, copper tungsten (CuW), or aluminum-silicon-carbide (AlSiC) or another applicable material. In some embodiments, the adhesive 352 is made of polymer having a good thermal conductivity.

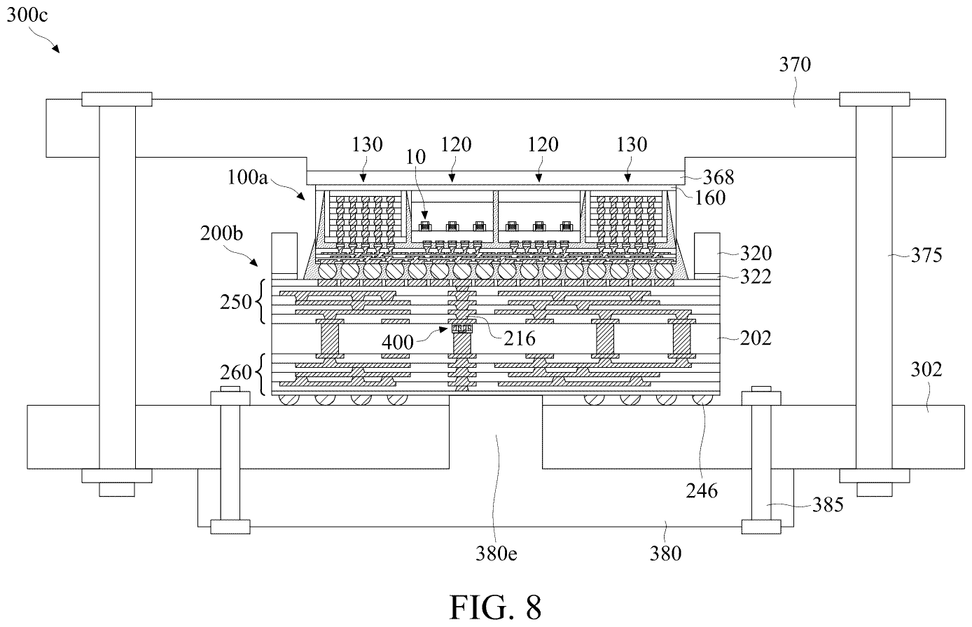

FIG. 8 shows a cross-sectional representation of a package structure 300c, in accordance with some embodiments of the disclosure. The package structure 300c is similar to, or the same as, the package structure 300a shown in FIGS. 1A-1O. Processes and materials used to form semiconductor device structure 300c may be similar to, or the same as, those used to form the semiconductor device structure 300a and a detailed description thereof is not repeated herein.

The difference between FIG. 8 and FIG. 1O is that the cooling device 400 is formed in the core substrate 202 to form a cooling substrate 200b. The packaged semiconductor structure 100a is bonded to the cooling substrate 200b.

The cooling device 400 is electrically connected to the conducive vias 216 and the conductive plug 204 of the front side interconnect structure 250. In addition, the heat can be transferred by the conducive vias 216 and the conductive plug 204. Therefore, the heat dissipation performance can be improved by the cooling device 400 of the cooling substrate 200b.

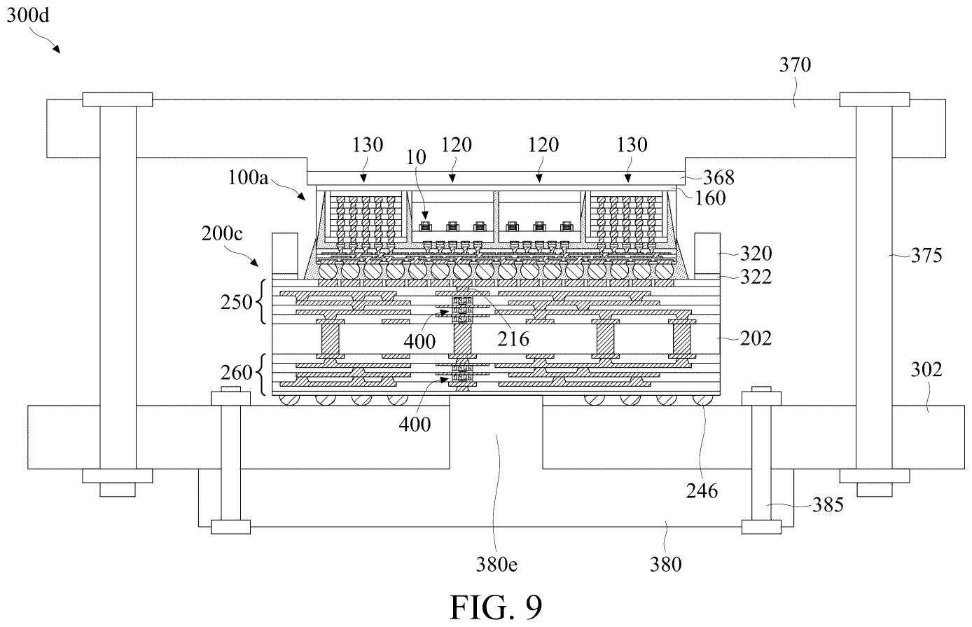

FIG. 9 shows a cross-sectional representation of a package structure 300d, in accordance with some embodiments of the disclosure. The package structure 300d is similar to, or the same as, the package structure 300a shown in FIGS. 1A-1O. Processes and materials used to form semiconductor device structure 300d may be similar to, or the same as, those used to form the semiconductor device structure 300a and a detailed description thereof is not repeated herein.

The difference between FIG. 9 and FIG. 1O is that a number of cooling devices 400 are formed in the front side interconnect structure 250, and a number of cooling devices 400 are formed in the back side interconnect structure 260 to form a cooling substrate 200c. The packaged semiconductor structure 100a is bonded to the cooling substrate 200c.

The number of the cooling devices 400 can be adjusted according to actual application. The number of cooling devices 400 can increase the heat dissipation performance. In addition, the heat can be transferred by the cooling devices 400 at front side and the back side to further improve heat dissipation efficiency.

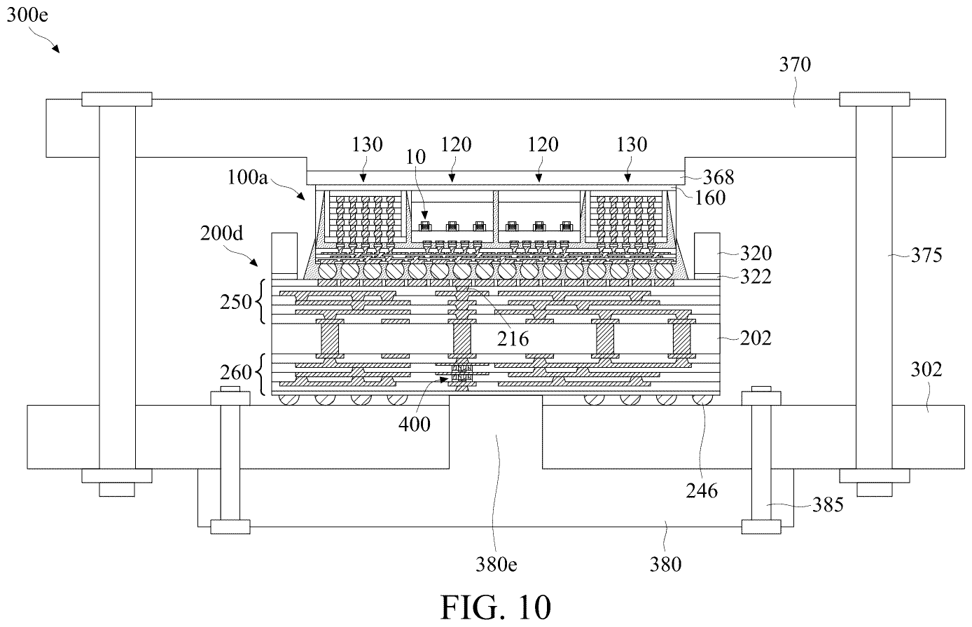

FIG. 10 shows a cross-sectional representation of a package structure 300e, in accordance with some embodiments of the disclosure. The package structure 300e is similar to, or the same as, the package structure 300a shown in FIGS. 1A-1O. Processes and materials used to form semiconductor device structure 300e may be similar to, or the same as, those used to form the semiconductor device structure 300a and a detailed description thereof is not repeated herein.

The difference between FIG. 10 and FIG. 1O is that a number of cooling devices 400 are formed in the back side interconnect structure 260 to form a cooling substrate 200d. The packaged semiconductor structure 100a is bonded to the cooling substrate 200c.

The number of the cooling devices 400 can be adjusted according to actual application. The number of cooling devices 400 can increase the heat dissipation performance.

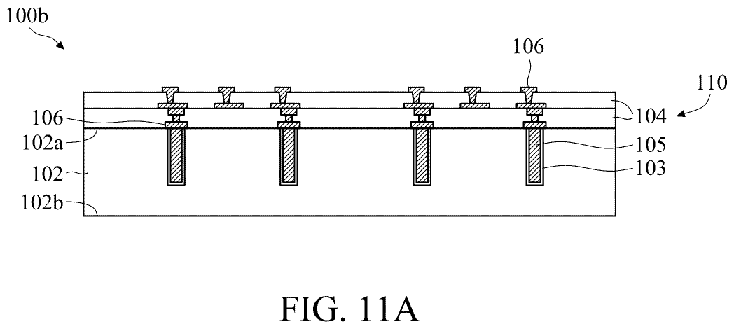

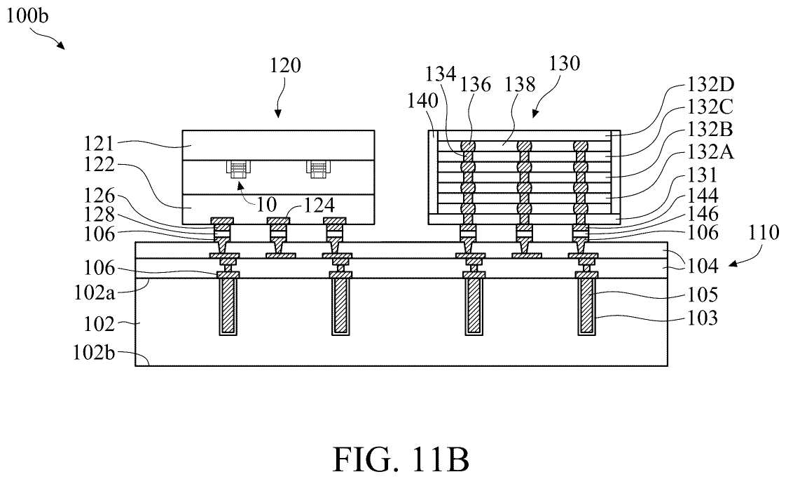

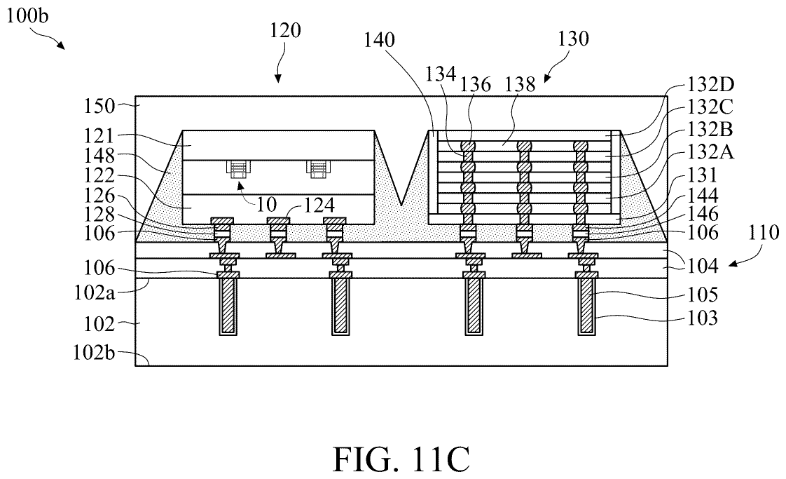

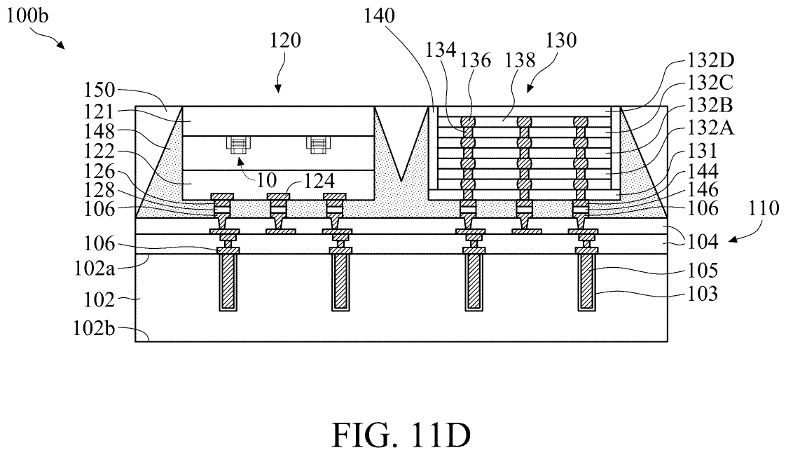

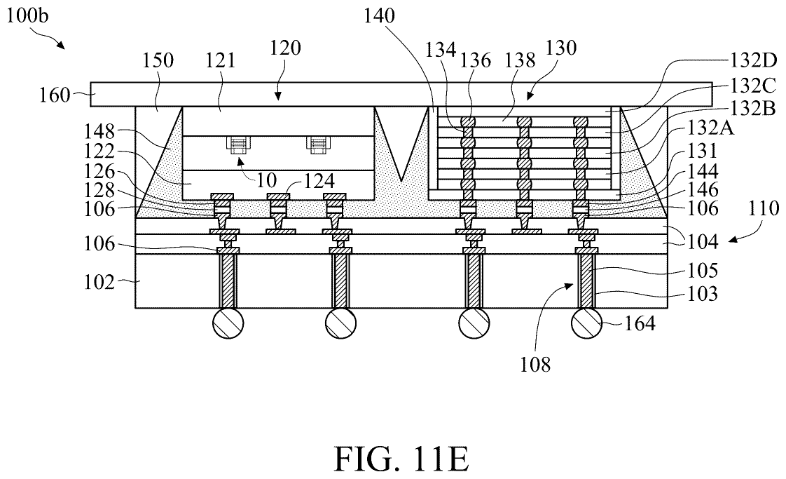

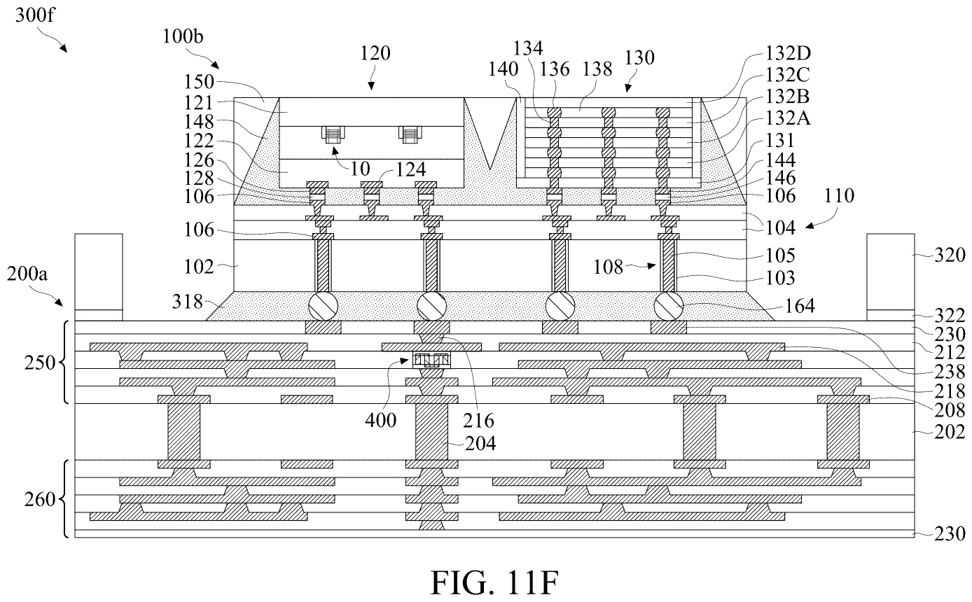

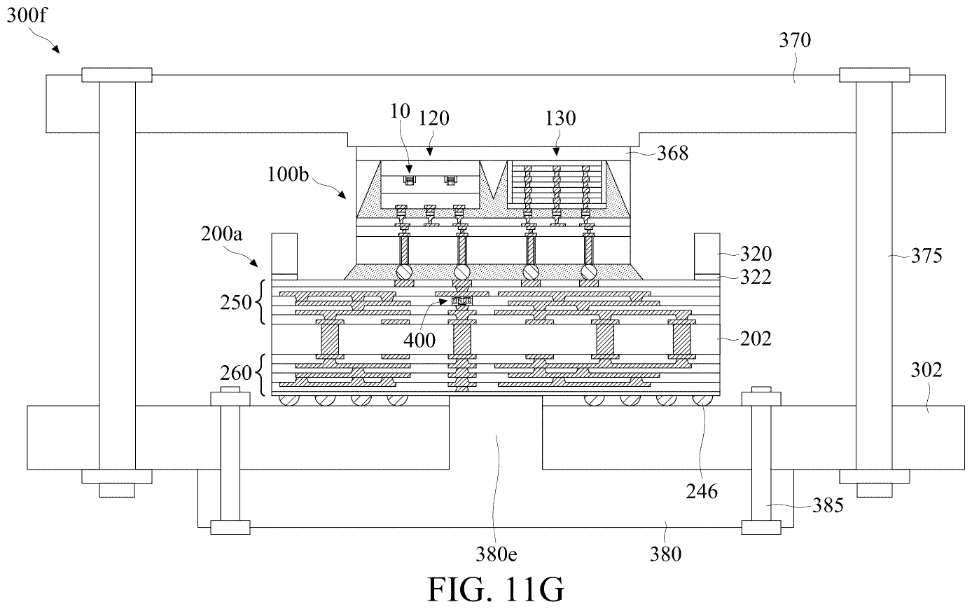

FIGS. 11A-11G shows a cross-sectional representation of a package structure 300f, in accordance with some embodiments of the disclosure. The package structure 300e is similar to, or the same as, the package structure 300a shown in FIGS. 1A-1O. Processes and materials used to form semiconductor device structure 300f may be similar to, or the same as, those used to form the semiconductor device structure 300a and a detailed description thereof is not repeated herein.

As shown in FIG. 11A, the conductive structures 105 are formed in the substrate 102. The conductive structures 105 extend from the front surface 102a of the substrate 102 towards the back surface 102b of the substrate 102. In some embodiments, the conductive structures 105 are formed by forming a number of trenches (not shown) which extend from the front surface 102a of the substrate 102. Afterwards, a barrier layer 103 is filled into each of the trenches, and the conductive structure 105 is formed on the barrier layer 103 and in each of the trenches.

The interconnect structure 110 is formed over the conductive structures 105 and the substrate 102. The interconnect structure 110 may be used as a redistribution (RDL) structure for routing. The interconnect structure 110 includes multiple conductive layers 106 formed in multiple dielectric layers 104. In some embodiments, the conductive layers 106 are exposed at or protruding from the top surface of the top of the dielectric layers 104 to serve as bonding pads.

The conductive structure 105 and the conductive layers 106 may be made of copper (Cu), copper alloy, aluminum (Al), aluminum alloy, tungsten (W), tungsten alloy, titanium (Ti), titanium alloy, tantalum (Ta) or tantalum alloy. In some embodiments, the conductive structures 105 and the conductive layers 106 are formed by an electroplating, electroless plating, printing, a chemical vapor deposition (CVD) process, or a physical vapor deposition (PVD) process.

Afterwards, as shown in FIG. 11B, the semiconductor dies 120 and the stacked die 130 are formed over the conductive layer 106, in accordance with some embodiments of the disclosure. The semiconductor die 120 includes the substrate 121 and the semiconductor structure 10 over the substrate 121.

The semiconductor structure 10 includes nanostructures (or called channel layers) 12 formed over the substrate 121, the inner spacer layers 14, the source/drain (S/D) structures 16, and the gate structure 18. The inner spacer layers 14 are between the nanostructures 12 and the S/D structures 16.

In some embodiments, the semiconductor dies 120 is sawed from a wafer, and may be a “known-good-die”. The first semiconductor die 120 may be a system-on-chip (SoC) chip or memory die.

In some embodiments, a number of conductive layers 126 are formed below the conductive pads 124 of the semiconductor dies 120, and each of the conductive layers 126 is bonded to each of the conductive layers 106 through a number of conductive connectors 128.

The stacked die 130 is disposed over the interconnect structure 110. The stacked die 130 is formed adjacent to the semiconductor die 120. The stacked die 130 includes a number of semiconductor dies 132A, 132B, 132C, 132D. In some embodiments, the semiconductor dies 132A, 132B, 132C, 132D are memory dies. The semiconductor die 120 has a different function from each of the plurality of the memory dies. The memory dies may include static random access memory (SRAM) devices, dynamic random access memory (DRAM) devices, high bandwidth memory (HBM) or another memory dies. The number of the semiconductor dies 132A, 132B, 132C, 132D are not limited to four, and the number can be adjusted according to the actual application.

Afterwards, as shown in FIG. 11C, the underfill layer 148 is formed between the semiconductor die 120, the tacked die 130 and the interconnect structure 110, in accordance with some embodiments of the disclosure. The underfill layer 148 surrounds and protects the conductive connectors 146 and the conductive connectors 128. In some embodiments, the underfill layer 148 is in direct contact with the conductive conductors 146 and the conductive connectors 128.

Afterwards, the first package layer 150 is formed over the underfill layer 148. The first package layer 150 is also formed over the substrate 122. The first package layer 150 surrounds and protects the semiconductor die 120 and the stacked die 130. In some embodiments, the first package layer 150 is in direct contact with a portion of the semiconductor die 120 and the stacked die 130.

Next, as shown in FIG. 11D, a portion of the first package layer 150 is removed to expose the top surface of the substrate 121, in accordance with some embodiments of the disclosure. In some embodiments, the portion of the first package layer 150 is removed by a planarization process, such as a chemical mechanical polishing (CMP) process.

Afterwards, as shown in FIG. 11E, the carrier substrate 160 is formed over the substrate 121 and the first package layer 150, and the structure as shown in FIG. 9D is flipped, in accordance with some embodiments of the disclosure. Next, the substrate 102 is thinned from the back surface 102b until the conductive structures 105 are exposed. In some embodiments, the conductive structures 105 and the barrier layer 103 become exposed and penetrate through the thinned substrate 102. As a result, the through via structures 108 are formed in the substrate 102. In some embodiments, the through via structures 108 are through substrate via (TSV) structures.

Afterwards, a number of the conductive connectors 164 are formed over the through via structures 108. In some embodiments, the conductive connectors 164 are referred to as controlled collapse chip connection (C4) bumps. In some other embodiments, the conductive connectors 164 is micro bumps, electroless nickel-electroless palladium-immersion gold technique (ENEPIG) formed bumps, ball grid array (BGA) bumps, or the like.

Next, as shown in FIG. 11F, the structure as shown in FIG. 11E is flipped and the carrier substrate 160 is removed to expose the top surface of the substrate 121, in accordance with some embodiments of the disclosure. As a result, an interposer 170 and a packaged semiconductor device 100b including the interposer 170 is obtained. The interposer 170 includes the through via structures 108 in the substrate 102 and the interconnect structure 110 electrically connected to the through via structures 108. The semiconductor dies 120 and the stacked die 130 are electrically connected to the conductive connectors 164 by the interposer 170.

Next, the packaged semiconductor device 100b is bonded to the cooling substrate 200a to form the package structure 300f. In some other embodiments, the cooling substrate 200a can be replaced with cooling substrate 200b, 200c or 200d.

Afterwards, as shown in FIG. 11G, the stiffener 320 is formed on edge portions of the protective layer 230, and the base substrate 302 is formed below the cooling substrate 200a, in accordance with some embodiments of the disclosure.

The conductive connectors 246 are formed below the back side interconnect structure 260 to electrically connect the base substrate 302. The package structure 300f including the cooling substrate 200a and the packaged semiconductor structure 100b is bonded to the base substrate 302 by the conductive connectors 246.

Next, the front side heat spreader 370 is formed on the packaged semiconductor structure 100b, and the back side spreader 380 is formed below the core substrate 202 of the cooling substrate 200a. The fastening element 375 is formed between the front side heat spreader 370 and the base substrate 302. The fastening element 375 may physically fasten the front side heat spreader 370 and the base substrate 302 together. The fastening element 385 is formed between the base substrate 302 and the backside heat spreader 380. The fastening element 385 may physically fasten the base substrate 302 and backside heat spreader 380 together. The fastening elements 385 include clamps, knob clamps, clips, other elements.

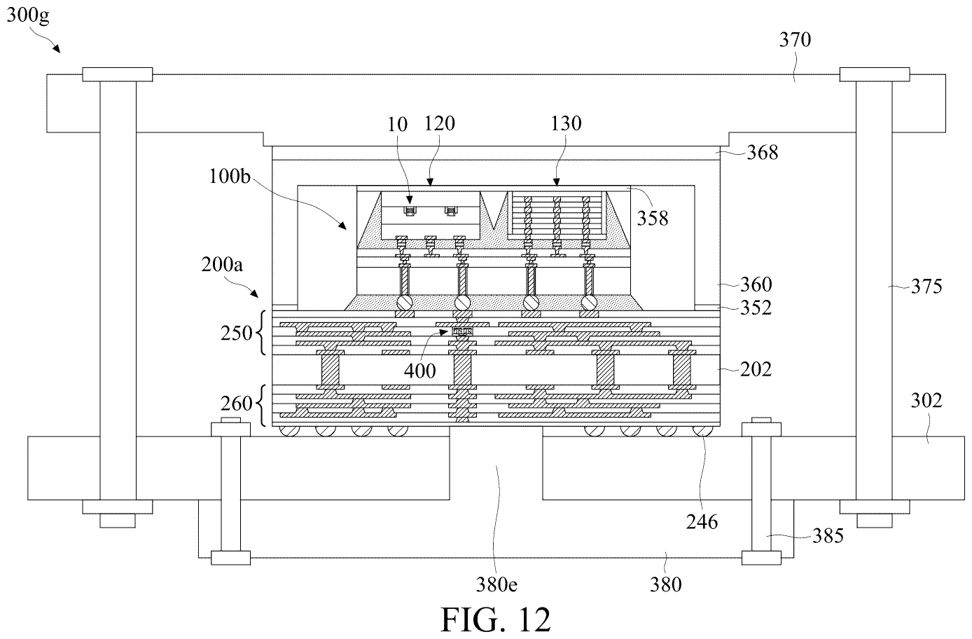

FIG. 12 shows a cross-sectional representation of a package structure 300g, in accordance with some embodiments of the disclosure. The package structure 300g is similar to, or the same as, the package structure 300f shown in FIGS. 11A-11G. Processes and materials used to form semiconductor device structure 300g may be similar to, or the same as, those used to form the semiconductor device structure 300f and a detailed description thereof is not repeated herein.

The difference between FIG. 12 and FIG. 11G is that there is an additional lid structure 360 between the front side heat spreader 370 and the package structure 300a. The TIM 358 is formed on the semiconductor device structure 100b, and between the lid structure 360 and the semiconductor device structure 100a. The TIM 368 is formed on the lid structure 360 and between the lid structure 360 and the front side heat spreader 370. The TIM 368 and the TIM 358 are formed on opposite sidewall surfaces of the lid structure 360. In some embodiments, the width of the TIM 368 is greater than the width of the TIM 358.

The semiconductor device structure 100b may be bonded to the cooling substrate 200b, the cooling substrate 200c or the cooling substrate 200d to form the package structure. In some embodiments, the semiconductor device structure 100b may be bonded to the cooling substrate 200b with the cooling device 400 in the core substrate 202. In some embodiments, the semiconductor device structure 100b may be bonded to the cooling substrate 200c with multiple cooling devices 400 in the front side interconnect structure 250 and in the back side interconnect structure 260. In some embodiments, the semiconductor device structure 100b may be bonded to the cooling substrate 200c with multiple cooling devices 400 in the back side interconnect structure 260.

It should be noted that the cooling device 400 is embedded in the cooling substrate 200a, 200b, 200c and 200d to help transfer the heat generated from the semiconductor die 120 or the stacked die 130. It should be noted that no logic device (transistor) is formed in the cooling substrates 200a, 200b, 200c and 200d, and the cooling substrates 200a, 200b, 200c and 200d provide the electrical and thermal routings.

The thermal path is not only at front side of the package structure 300a, 300b, 300c, 300d, 300e, 300f, but also at back side, therefore the heat dissipation efficiency of the package structure 100b can be improved.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming a package structure and method for formation the same are provided. The package structure includes a packaged semiconductor device bonded to a cooling substrate. The packaged semiconductor device includes a die. The cooling substrate includes a cooling device. The hot spots are general close to the die. Thus, the cooling device is directly below the die of the packaged semiconductor structure to help transfer the heat from the die to the outer heat spreader. In addition, the front side heat spreader and the back side heat spreader are formed on opposite sidewall surfaces of the cooling substrate to improve the heat dissipation efficiency. Therefore, the heat dissipation efficiency of the package structure is improved.

In some embodiments, a package structure is provided. The package structure includes a cooling substrate formed on a base substrate, and the cooling substrate comprises a cooling device. The package structure includes a packaged semiconductor device formed on the cooling substrate, and the packaged semiconductor device comprises a first die, and the cooling device is directly below the first die.

In some embodiments, a package structure is provided. The package structure includes a cooling substrate formed on a base substrate, and the cooling substrate comprises a thermal electronic cooler (TEC). The package structure includes a packaged semiconductor device formed on the cooling substrate, and the packaged semiconductor device comprises a first die. The package structure includes a back side heat spreader formed below the cooling substrate. The back side heat spreader comprises an extending portion through the base substrate, and the extending portion of the back side heat spreader is connected to the cooling substrate.

In some embodiments, a method for forming a package structure is provided. The method includes forming a front side interconnect structure over a core substrate, and forming a cooling device in the front side interconnect structure or the core substrate to form a cooling substrate. The method includes bonding a packaged semiconductor device to the cooling substrate, and the packaged semiconductor device comprises a first die, and the cooling device is directly below the first die. The method includes bonding the cooling substrate to a base substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a cooling substrate formed on a base substrate, wherein the cooling substrate comprises a cooling device; and
a packaged semiconductor device formed on the cooling substrate, wherein the packaged semiconductor device comprises a first die, and the cooling device is directly below the first die.

2. The package structure as claimed in claim 1, wherein the cooling substrate comprises:
a core substrate;
a front side interconnect structure formed on the core substrate; and
a back side interconnect structure formed below the core substrate, wherein the cooling device is formed in the front side interconnect structure.

3. The package structure as claimed in claim 2, wherein the cooling device is formed in the core substrate.

4. The package structure as claimed in claim 2, further comprising:
another cooling device formed in the back side interconnect structure.

5. The package structure as claimed in claim 1, further comprising:
a front side heat spreader formed on the packaged semiconductor device.

6. The package structure as claimed in claim 1, further comprising:
a back side heat spreader formed below the cooling substrate, wherein the back side heat spreader comprises an extending portion through the base substrate, and the extending portion of the back side heat spreader is connected to the cooling substrate.

7. The package structure as claimed in claim 1, wherein the cooling substrate comprises a plurality of vias, and the vias are electrically connected to the cooling device.

8. The package structure as claimed in claim 6, further comprising:
a back side fastening element connecting the base substrate and the back side heat spreader.

9. The package structure as claimed in claim 1, further comprising:
a stiffener formed on the cooling substrate, wherein the packaged semiconductor device is surrounded by the stiffener.

10. A package structure, comprising:
a cooling substrate formed on a base substrate, wherein the cooling substrate comprises a thermal electronic cooler (TEC);
a packaged semiconductor device formed on the cooling substrate, wherein the packaged semiconductor device comprises a first die; and
a back side heat spreader formed below the cooling substrate, wherein the back side heat spreader comprises an extending portion through the base substrate, and the extending portion of the back side heat spreader is connected to the cooling substrate.

11. The package structure as claimed in claim 10, wherein the cooling substrate comprises a plurality of vias, and the vias are electrically connected to the thermal electronic cooler (TEC).

12. The package structure as claimed in claim 10, further comprising:
a front side heat spreader formed on the packaged semiconductor device.

13. The package structure as claimed in claim 12, further comprising:
a fastening element connecting the front side heat spreader and the back side heat spreader.

14. The package structure as claimed in claim 10, wherein the cooling substrate comprises:
a first thermal interface material (TIM) on the packaged semiconductor device;
a lid structure formed on the first TIM;
a second TIM formed on the lid structure; and
a front side heat spreader formed on the second TIM.

15. The package structure as claimed in claim 10, further comprising:
a back side fastening element connecting the base substrate and the back side heat spreader.

16. The package structure as claimed in claim 10, wherein the first die comprises:
a plurality of nanostructures;
an S/D structure connected to the nanostructures;
a gate structure wrapped around the nanostructures; and
an inner spacer layer between the gate structure and the S/D structure.

17. A method for forming a package structure, comprising:
forming a front side interconnect structure over a core substrate;
forming a cooling device in the front side interconnect structure or the core substrate to form a cooling substrate;
bonding a packaged semiconductor device to the cooling substrate, wherein the packaged semiconductor device comprises a first die, and the cooling device is directly below the first die; and
bonding the cooling substrate to a base substrate.

18. The method for forming the package structure as claimed in claim 17, further comprising:
forming a front side heat spreader on the packaged semiconductor device.

19. The method for forming the package structure as claimed in claim 17, further comprising:
forming a trench in the base substrate; and
forming a back heat spreader in the trench and below the carrier substrate, wherein the back heat spreader comprises an extending portion that extends through the trench.

20. The method for forming the package structure as claimed in claim 17, further comprising:
forming a back side interconnect structure below the base substrate; and
forming another cooling device in the back side interconnect structure.
